(19) United States
(12) Patent Application Publication
(10) Pub. No.: US 2025/0180961 A1
(43) Pub. Date: Jun. 5, 2025

(54) OPTICAL PATH CONTROL MEMBER AND DISPLAY DEVICE COMPRISING SAME

(71) Applicant: LG INNOTEK CO., LTD., Seoul (KR)

(72) Inventors: Jong Sik LEE, Seoul (KR); Jin Gyeong PARK, Seoul (KR); Jun LEE, Seoul (KR)

(21) Appl. No.: 18/837,590

(22) PCT Filed: Feb. 1, 2023
(86) PCT No.: PCT/KR2023/001433

§ 371 Date: Aug. 10, 2024

(30) Foreign Application Priority Data
Feb. 10, 2022 (KR) 10-2022-0017721

(51) Int. Cl. G02F 1/17; G02F 1/13; G02F 1/1339; H10K 59/80

(52) U.S. Cl. CPC G02F 1/172; G02F 1/1323; G02F 1/1339; H10K 59/8722

(57) ABSTRACT

An optical path control member according to an embodiment includes a first substrate; a first electrode disposed on the first substrate; an adhesive layer disposed on the first electrode; a light conversion part disposed on the adhesive layer; a second electrode disposed on the light conversion part; and a second substrate disposed on the second electrode, wherein a cutting region is formed by removing the second substrate, the second electrode, the light conversion part, and the adhesive layer, at least one protrusion is provided in the cutting region while extending in a direction from the first electrode toward the second substrate, and a sealing part is disposed in the cutting region.

### TECHNICAL FIELD

An embodiment relates to an optical path control member and a display device including the same.

### BACKGROUND ART

A light blocking film is a film that blocks transmission of light from a light source. The light blocking film is attached to a front of the display panel, which is a display device used for a mobile phone, a laptop, a tablet PC, a vehicle navigation, or a vehicle touch. The light blocking film adjusts a viewing angle of light according to an incident angle of light when the display device transmits a screen. Thereby, the user can visually recognize clear image quality at a desired viewing angle.

In addition, the light blocking film is used for windows of vehicles or buildings. In detail, the light blocking film may prevent glare by partially shielding external light. Alternatively, the light blocking film may prevent an inside from being seen from an outside.

That is, the light blocking film controls a movement path of light. Thereby, the light blocking film may block light in a set range and transmit light in a set range. Accordingly, a transmission angle of light is controlled by the light blocking film.

The light blocking film may be divided into a light blocking film capable of always controlling a viewing angle regardless of a surrounding environment and a switchable light blocking film capable of turning on and off a viewing angle control by a user according to a surrounding environment.

The switchable light blocking film includes a light conversion part including a receiving part. An inside of the receiving part is filled with a light conversion material including particles and a dispersion. The particles may move by an application of a voltage. The receiving part may be converted into a light transmitting part and a light blocking part by dispersion and aggregation of the particles.

In this case, in order to transmit a voltage to the light blocking film, an electrode of the light blocking film is connected to an external power source. An electrode connected to the external power source is disposed in a bezel region of the light blocking film.

Meanwhile, the light blocking film includes an adhesive layer. The adhesive layer has a low moisture permeability. Accordingly, moisture may penetrate into the light blocking film through the adhesive layer.

Accordingly, the reliability of the light blocking film may be reduced. For example, the appearance of the light blocking film may be defective. In addition, properties of the light conversion material may be changed. Accordingly, the driving characteristics of the light blocking film may be reduced.

Therefore, a new structure of an optical path control member capable of solving the problems is required.

### DISCLOSURE

### Technical Problem

An embodiment provides an optical path control member having improved reliability and driving characteristics.

### Technical Solution

An optical path control member according to an embodiment comprises a first substrate; a first electrode disposed on the first substrate; an adhesive layer disposed on the first electrode; a light conversion part disposed on the adhesive layer; a second electrode disposed on the light conversion part; and a second substrate disposed on the second electrode, wherein a cutting region is formed by removing the second substrate, the second electrode, the light conversion part, and the adhesive layer, wherein at least one protrusion is provided in the cutting region while extending in a direction from the first electrode toward the second substrate, and wherein a sealing part is disposed in the cutting region.

### Advantageous Effects

A sealing part of an optical path control member according to an embodiment has improved adhesive force.

The sealing part is disposed inside the cutting region, and a protrusion is formed inside the cutting region. Accordingly, a contact area of the sealing part may be increased. Accordingly, it is possible to prevent the sealing part from being peeled off.

In addition, the optical path control member according to the embodiment has a reduced bezel region.

In detail, a protrusion is formed inside the cutting region. The cutting region is partially separated by the protrusion. Accordingly, the cutting region may include a plurality of cutting regions.

The plurality of cutting regions are formed to have different sizes. For example, the plurality of cutting regions may have different widths and depths.

A size of a cutting region adjacent to a receiving part among a plurality of cutting regions may be formed to be large. In addition, a size of a cutting region far from the receiving part may be formed small. Accordingly, the bezel region may be reduced while maintaining the sealing characteristics.

Accordingly, the optical path control member according to an embodiment may have improved reliability. Also, the optical path control member according to an embodiment may have a narrow bezel.

### DESCRIPTION OF DRAWINGS

FIG. 1 is a perspective view of an optical path control member according to an embodiment.

FIG. 2 is a top view of a first substrate of an optical path control member according to an embodiment.

FIG. 3 is a top view of a second substrate of an optical path control member according to an embodiment.

FIG. 4 is a top view of a second substrate in which a first substrate and a second substrate are laminated.

FIGS. 5 and 6 are cross-sectional views taken along a A-A′ region of FIG. 4.

FIG. 7 is a cross-sectional view taken along a B-B′ region of FIG. 4.

FIG. 8 is a cross-sectional view taken along a C-C′ region of FIG. 4.

FIGS. 9 to 18 are various cross-sectional views taken along a D-D′ region of FIG. 4.

FIGS. 19 and 20 are cross-sectional views of a display device to which an optical path control member according to an embodiment is applied.

FIGS. 21 to 23 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings. The optical path control member described below may operate in a publication mode and a light blocking mode depending on the application of power. That is, the optical path control member may be a switchable light blocking film.

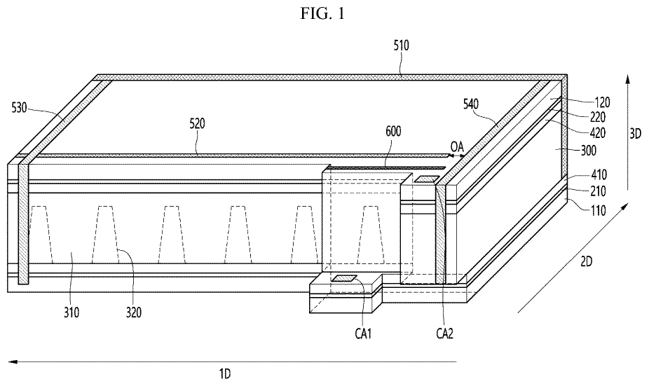

FIG. 1 is a diagram showing a perspective view of an optical path control member according to an embodiment.

Referring to FIG. 1, the optical path control member 1000 according to the embodiment includes a first substrate 110, a second substrate 120, a first electrode 210, a second electrode 220, and a light conversion part 300.

The first substrate 110 may support the first electrode 210. The first substrate 110 may be rigid or flexible.

In addition, the first substrate 110 may be transparent. For example, the first substrate 110 may include a transparent substrate capable of transmitting light.

The first substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS).

In addition, the first substrate 110 may be a flexible substrate having flexible characteristics.

In addition, the first substrate 110 may be a curved or bent substrate. That is, the optical path control member including the first substrate 110 may also be formed to have flexible, curved, or bent characteristics. Accordingly, the optical path control member according to an embodiment may be provided in various designs.

The first substrate 110 may extend in a first direction 1D, a second direction 2D, and a third direction 3D.

Specifically, the first direction 1D and the second direction 2D may correspond to a longitudinal direction or a width direction of the optical path control member. Also, the first direction 1D and the second direction 2D may be different directions. Also, the third direction 3D may correspond to a thickness direction of the optical path control member.

Hereinafter, for convenience of description, the first direction 1D is defined in a longitudinal direction of the optical path control member. Also, the second direction 2D is defined in a width direction of the optical path control member. Also, the third direction 3D is defined in a thickness direction of the optical path control member.

The first substrate 110 may have a thickness within a predetermined range. For example, the first substrate 110 may have a thickness of 25 to 150 μm.

The first electrode 210 is disposed on one surface of the first substrate 110. Specifically, the first electrode 210 is disposed on an upper surface of the first substrate 110. The first electrode 210 is disposed between the first substrate 110 and the second substrate 120.

The first electrode 210 may include a transparent conductive material. For example, the first electrode 210 may include a conductive material having a light transmittance of 80% or more. For example, the first electrode 210 may include indium tin oxide, indium zinc oxide, copper oxide, tin oxide, zinc oxide, or titanium oxide, etc.

A thickness of the first electrode 210 may be about 10 nm to about 300 nm.

Alternatively, the first electrode 210 may include various metals to realize low resistance. For example, the first electrode 210 may include at least one of chromium (Cr), nickel (Ni), copper (Cu), aluminum (Al), silver (Ag), molybdenum (Mo). Gold (Au), titanium (Ti), and alloys thereof. Accordingly, the first electrode 210 may have a low resistance.

The first electrode 210 may be entirely disposed on one surface of the first substrate 110. Specifically, the first electrode 210 may be disposed as a surface electrode on one surface of the first substrate 110. However, the embodiment is not limited thereto. The first electrode 210 may include a plurality of pattern electrodes. The pattern electrode may be formed in a mesh shape or a stripe shape.

For example, the first electrode 210 may include a plurality of mesh lines that cross each other and a plurality of mesh openings formed by the mesh lines.

Accordingly, the first electrode is not visually recognized from the outside. In addition, a light transmittance may be increased by the opening. Accordingly, a luminance of the optical path control member may be improved.

The second substrate 120 is disposed on the first substrate 110. Specifically, the second substrate 120 is disposed on the first electrode 210.

The second substrate 120 may include the same or similar material as or to the first substrate 110.

In addition, the second substrate 120 may have a thickness that is the same as or similar to that of the first substrate 110. For example, the thickness of the second substrate 120 may be 25 μm to 150 μm.

In addition, the second substrate 120 may extend in the first direction 1D, the second direction 2D, and the third direction 3D.

The second electrode 220 is disposed on one surface of the second substrate 120. Specifically, the second electrode 220 is disposed on a lower surface of the second substrate 120. That is, the second electrode 220 is disposed on a surface where the second substrate 120 and the first substrate 110 face each other. That is, the second electrode 220 faces the first electrode 210. That is, the second electrode 220 is disposed between the first electrode 210 and the second substrate 120.

The second electrode 220 may include the same or similar material as or to the first electrode 210.

In addition, the second electrode 220 may have a thickness that is the same as or similar to that of the first electrode 210. For example, the thickness of the second electrode 220 may be about 10 nm to about 300 nm.

Also, the second electrode 220 may be formed in the same shape or shape as the first electrode 210.

The first substrate 110 and the second substrate 120 may have the same size or different sizes.

Specifically, the first substrate 110 defines a first length in a first direction 1D. Furthermore, the second substrate 120 defines a second length in a first direction 1D. The first length and the second length may be the same or similar.

For example, the first length and the second length may be 300 mm to 400 mm.

The first substrate 110 defines a first width in a second direction 2D. Furthermore, the second substrate 120 defines a second width in a second direction 2D. The first width and the second width may be the same or similar.

For example, the first width and the second width may be 150 mm to 200 mm.

Also, the first substrate 110 and the second substrate 120 may be formed to have different areas.

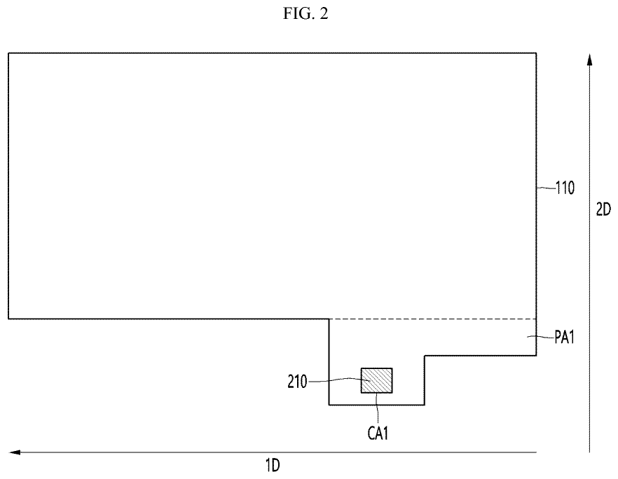

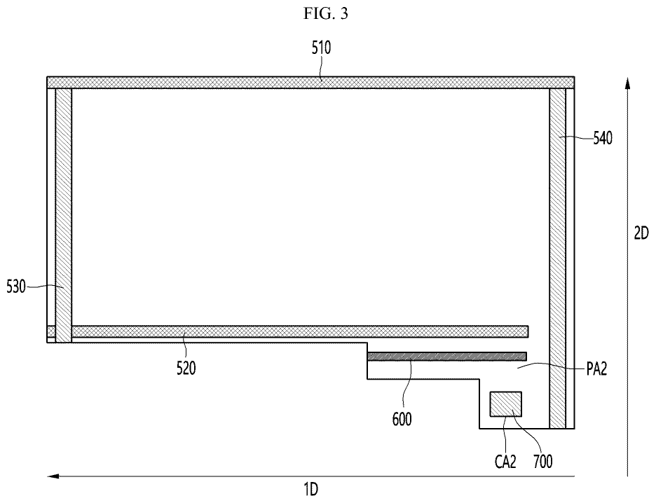

Each of the first substrate 110 and the second substrate 120 may include protrusions. Referring to FIGS. 2 and 3, the first substrate 110 includes a first protrusion PA1. The second substrate 120 includes a second protrusion PA2. Specifically, the first protrusion PA1 and the second protrusion PA2 may be disposed to be misaligned with each other. Specifically, the first protrusion PA1 and the second protrusion PA2 do not overlap each other in the third direction 3D.

Alternatively, the first protrusion PA1 and the second protrusion PA2 may include an overlapping region and a non-overlapping region.

The first protrusion PA1 and the second protrusion PA2 may have different areas. Accordingly, the first substrate 110 and the second substrate 120 may have different sizes according to the area of the protrusion.

The first protrusion PA1 and the second protrusion PA2 include a connection region. The connection region is connected to an external printed circuit board.

The first protrusion PA1 includes a first connection region CA1. The second protrusion PA2 includes a second connection region CA2.

The first electrode 210 is exposed to the first connection region CA1. Also, a conductive material is exposed to the second connection region CA2. For example, a cutting region is formed in the second protrusion PA2. An inside of the cutting region is filled with a conductive material 700. Accordingly, the second connection region CA2 may be formed.

The optical path control member may be electrically connected to an external printed circuit board by the connection regions CA1 and CA2.

For example, a pad part is disposed on the first connection region CA1 and the second connection region CA2, and a conductive adhesive is disposed between the pad part and a terminal of the printed circuit board. The conductive adhesive may include an anisotropic conductive film (ACF) or anisotropic conductive paste (ACP). Accordingly, the optical path control member may be connected to an external printed circuit board.

Alternatively, the connection region of the optical path control member may be directly connected to an external printed circuit board without the pad part.

The light conversion part 300 is disposed between the first substrate 110 and the second substrate 120. Specifically, the light conversion part 300 is disposed between the first electrode 210 and the second electrode 220.

An adhesive layer 410 is disposed between the first electrode 210 and the light conversion part 300. Accordingly, the first substrate 110 and the light conversion part 300 are adhered to each other.

The adhesive layer 410 may have a thickness within a set range. For example, the adhesive layer 410 may have a thickness of 10 μm to 30 μm.

Also, a buffer layer 420 is disposed between the second electrode 220 and the light conversion part 300. Accordingly, the adhesion between the second electrode 220 and the light conversion part 300 is improved.

The buffer layer 420 may have a thickness within a set range. For example, the thickness of the buffer layer 420 may be less than 1 μm.

The light conversion part 300 includes a plurality of partition wall parts 310 and a receiving part 320. A light conversion material 330 is disposed inside the receiving part 320.

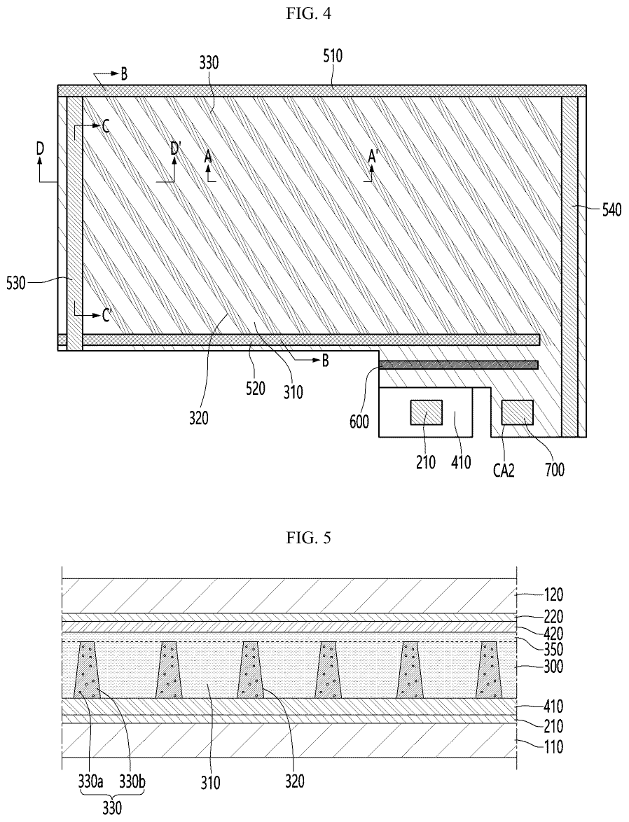

Referring to FIGS. 3 and 4, the receiving part 320 extends in one direction. Specifically, the receiving part 320 is tilted at an angle within a set range.

For example, the receiving part 320 may extend in a direction different from the first and second directions 1D and 2D. That is, the receiving part 320 may extend by being tilted in the first and second directions 1D and 2D. For example, the receiving part 320 may extend in a direction between the first and second directions 1D and 2D.

Accordingly, a receiving part of at least one of the receiving parts contacts a first sealing part 510 and a second sealing part 520. Also, a receiving part of at least one of the receiving parts contacts a first sealing part 510 and a fourth sealing part 540. Also, a receiving part of at least one of the receiving parts contacts a second sealing part 520 and a third sealing part 530.

Accordingly, the receiving parts 320 may be sealed by the same or different sealing parts.

For example, all of the receiving parts 320 may be sealed by the first sealing part 510 and the second sealing part 520.

Alternatively, at least one receiving part of the receiving parts is sealed by the first sealing part 510 and the second sealing part 520. Also, at least one receiving part of the receiving parts is sealed by the first sealing part 510 and the fourth sealing part 540. Also, at least one receiving part of the receiving parts is sealed by the second sealing part 520 and the third sealing part 530.

The receiving part 320 is tilted at an inclination angle within a range set with respect to the first direction 1D and the second direction 2D. Accordingly, when the optical path control member and the display panel are combined to form a display device, a moiré phenomenon caused by overlapping the receiving part and a pattern part of the display panel may be prevented.

Since the receiving part 320 is tilted, lengths of each receiving part may be different. In detail, the length of the receiving part 320 may be changed while extending in the first direction 1D. In more detail, the length of the receiving part 320 may increase and decrease while moving from the third sealing part 530 toward the fourth sealing part 540.

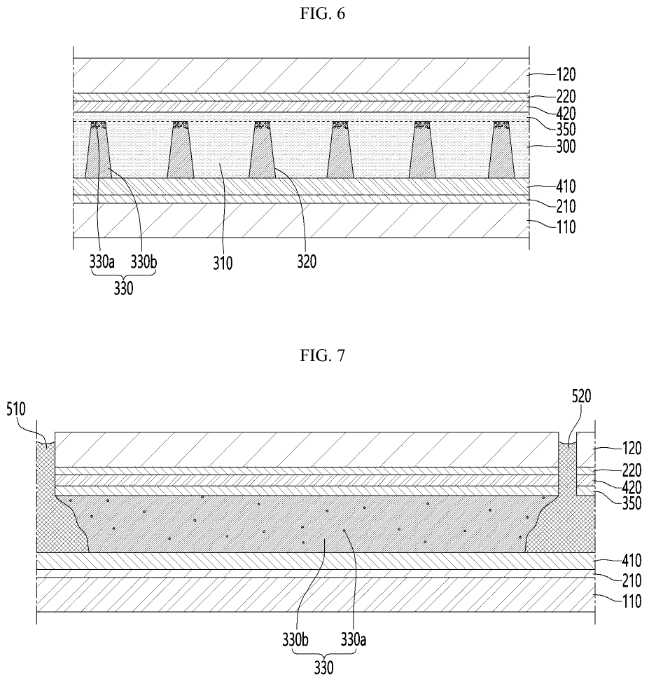

FIGS. 5 and 6 are cross-sectional views taken along a A-A′ region of FIG. 4.

Referring to FIGS. 5 and 6, the light conversion part 300 includes a partition wall part 310 and an receiving part 320.

The partition wall part 310 is defined as a partition wall region that divides the receiving part. That is, the partition wall part 310 may transmit light.

The partition wall part 310 and the receiving part 320 are disposed with different widths. For example, the width of the partition wall part 310 is greater than the width of the receiving part 320.

In addition, the width of the receiving part 320 may be narrowed while extending from the first electrode 210 toward the second electrode 220.

The partition wall part 310 and the receiving part 320 are alternately disposed. That is, each of the partition wall parts 310 is disposed between the adjacent receiving parts 320. Also, each receiving part 320 is disposed between the adjacent partition wall parts 310.

The partition wall part 310 may include a transparent material. The partition wall part 310 may include a material capable of transmitting light.

The partition wall part 310 may include a resin material. For example, the partition wall part 310 may include a photocurable resin material. For example, the partition wall part 310 may include a UV resin or a transparent photoresist resin. Alternatively, the partition wall part 310 may include a urethane resin or an acrylic resin.

The receiving part 320 may be formed by partially passing through the light conversion part 300. Accordingly, the receiving part 320 is in contact with the adhesive layer 410. In addition, the receiving part 320 is spaced apart from the buffer layer 420. Accordingly, a base part 350 is formed between the receiving part 320 and the buffer layer 420.

The light conversion material 330 is disposed inside the receiving part 320. The light conversion material 330 includes light conversion particles 330a and a dispersion 330b. The light conversion particles 330a are dispersed in the dispersion 330b.

The dispersion 330b may include a transparent material. The dispersion 330b may include a non-polar solvent. The dispersion 330b may include a material capable of transmitting light. For example, the dispersion 330b may include at least one material among halocarbon-based oil, paraffin-based oil, and isopropyl alcohol.

The light conversion particle 330a may include a material capable of absorbing light. That is, the light conversion particle 330a may be a light absorbing particle. The light conversion particle 330a may have a color. For example, the light conversion particle 330a may have a black-based color. For example, the light conversion particle 330a may include a carbon black particle.

A surface of the light conversion particle 330a is charged. Accordingly, the surface of the light conversion particle 330a may have a polarity. For example, the surface of the light conversion particle 330a may be charged with a cathode. Accordingly, the light conversion particle 330a may be moved toward the first electrode 210 or the second electrode 220 by the application of a voltage.

The light transmittance of the receiving part 320 is changed by the light conversion particles 330a. Specifically, the light transmittance of the receiving part 330a is changed by a movement of the light conversion particles 330a.

For example, the optical path control member may be switched to a first mode and a second mode by an applied voltage.

Specifically, in the first mode, the receiving part 320 operates as a light blocking part. Accordingly, light within a set range may be blocked. Accordingly, the viewing angle of the user viewed from the outside is narrowed. Thereby, the optical path control member is driven in a privacy mode.

Also, in the second mode, the receiving part 320 operates as a light transmitting part. Accordingly, light is transmitted from both the partition wall part 310 and the receiving part 320. Accordingly, the viewing angle of the user viewed from the outside is widened. Accordingly, the optical path control member is driven in a publication mode.

The first mode and the second mode may be driven by the movement of the light conversion particle 330a.

For example, when a voltage is not applied to the optical path control member, the light conversion particles 330a are uniformly dispersed in the dispersion 330b. Accordingly, the light of the receiving part 320 is blocked by the light conversion particles 330a. Accordingly, as shown in FIG. 5, the receiving part 320 may be driven as the light blocking part.

In addition, when a voltage is applied to the optical path control member from the outside, the light conversion particles 330a move. For example, the light conversion particles 330a move toward the first electrode 210 or the second electrode 220. Therefore, as shown in FIG. 6, the receiving part 320 may be driven by a light transmission part.

For example, when a voltage is applied to the first electrode 210 and/or the second electrode 220, an electric field is formed between the first electrode 210 and the second electrode 220. Accordingly, a negatively charged light conversion particle 330a moves using the dispersion 330b as a medium. Specifically, the light conversion particle 330a moves in a direction of a positive electrode among the first electrode 210 and the second electrode 220.

Accordingly, the optical path control member according to an embodiment may be driven in two modes according to the user's environment.

Referring to FIGS. 1, 4, and 7 to 18, the optical path control member includes a sealing part. The sealing part seals the light conversion material inside the receiving part 320. Also, the sealing part prevents moisture from penetrating.

The sealing part may include a sealing part extending in the first direction 1D and a sealing part extending in the second direction 2D. For example, the sealing part may include a first sealing part 510 and a second sealing part 520 extending in the first direction 1D. The first sealing part 510 and the second sealing part 520 face each other in the second direction 2D.

The first sealing part 510 and the second sealing part 520 seal the light conversion material 330 disposed inside the receiving part 320.

In addition, the sealing part may include a third sealing part 530 and a fourth sealing part 540 extending in the second direction 2D. The third sealing part 530 and the fourth sealing part 540 face each other in the first direction 1D.

The third sealing part 530 and the fourth sealing part 540 seal the light conversion material 330 disposed inside the receiving part 320. Also, the third sealing part 530 and the fourth sealing part 540 prevent moisture from penetrating into the optical path control member.

The sealing parts 510, 520, 530, and 540 may be disposed at an edge region of the optical path control member.

Also, the sealing parts 510, 520, 530, and 540 may be connected to each other. Specifically, the sealing parts 510, 520, 530, and 540 are connected to each other except for an open region OA. The open region OA is a region for conducting the second connection region CA2 and the second electrode 220.

The sealing parts 510, 520, 530, and 540 may be formed by forming a cutting region in the optical path control member 1000.

For example, the cutting region is formed by removing the second substrate 120, the second electrode 220, the buffer layer 420, the light conversion part 300, and the adhesive layer 410. The sealing parts 510, 520, 530, and 540 are disposed in the cutting region.

Specifically, the light conversion material 330 is injected into the receiving part 320 through the cutting region. Subsequently, the sealing material is filled in the cutting region. Accordingly, the light conversion material 330 is sealed by the sealing material. For example, the cutting region in which the first sealing part 510 is disposed may be an injection part for injecting a light conversion material. Also, the cutting region in which the second sealing part 520 is disposed may be a suction part for sucking the light conversion material.

In addition, a dam part 600 may be additionally disposed under the second sealing part 520 to prevent overflow when the light conversion material is injected.

The sealing parts 510, 520, 530, and 540 may be in contact with both ends of the receiving part 320. Accordingly, the light conversion material 330 does not flow out of the receiving part 320 due to the sealing parts 510, 520, 530, and 540.

The sealing parts 510, 520, 530, and 540 may be disposed inside the receiving part 320. Specifically, a part of the sealing parts 510, 520, 530, and 540 may be disposed inside the receiving part 320.

For example, as shown in FIGS. 7, 9 to 18, the sealing parts 510, 520, 530, and 540 are formed by injecting a sealing material into the cutting region and curing the sealing material. The sealing material has fluidity before curing. Therefore, the sealing material may be introduced into the receiving part while pushing a light conversion material disposed inside the receiving part.

Accordingly, some regions of the sealing parts 510, 520, 530, and 540 may be disposed inside the receiving part 320.

Accordingly, it is possible to prevent impurities from flowing into the receiving part 320 by the sealing parts 510, 520, 530, and 540.

Moisture may be prevented from flowing into the optical path control member by the sealing parts 510, 520, 530, and 540. However, the adhesive layer is very vulnerable to moisture. Accordingly, moisture may be introduced into the optical path control member through the adhesive layer.

Hereinafter, an optical path control member capable of blocking moisture introduced through the adhesive layer will be described.

Hereinafter, for convenience of description, the third sealing part 530 will be mainly described. However, embodiments are not limited thereto. That is, the description described below may be applied to the other sealing parts 510, 520, and 540.

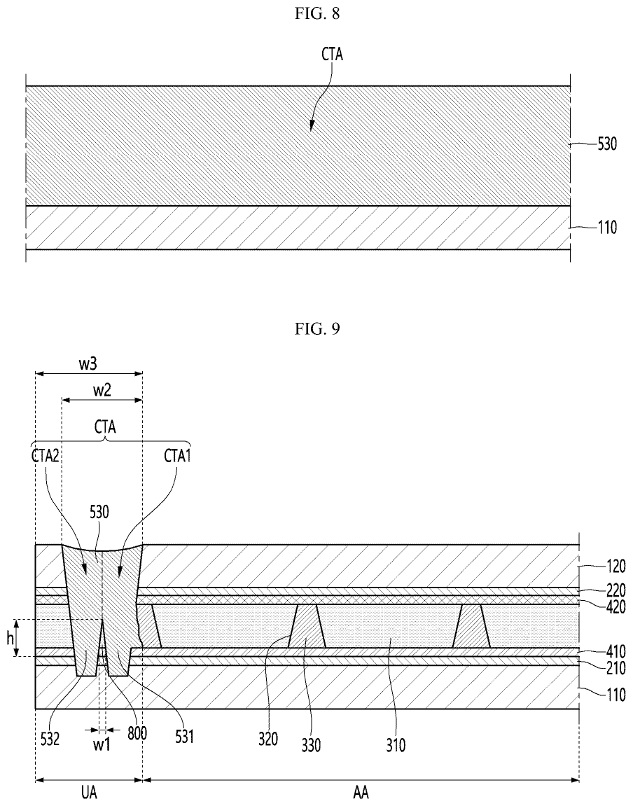

FIG. 8 is a cross-sectional view taken along a C-C′ region of FIG. 4, and FIGS. 9 to 18 are various cross-sectional views taken along a D-D′ region of FIG. 4.

Referring to FIG. 8, the third sealing part 530 is disposed inside the cutting region CTA. The cutting region CTA is formed by partially cutting the optical path control member.

In detail, the cutting region CTA may be formed by cutting at least one of the second substrate 120, the second electrode 220, the buffer layer 420, the light conversion part 300, the adhesive layer 410, the first electrode 210, and the first substrate 110. In more detail, the cutting region CTA may be formed by cutting the second substrate 120, the second electrode 220, the buffer layer 420, the light conversion part 300, the adhesive layer 410, the first electrode 210, and the first substrate 110. For example, the second substrate 120, the second electrode 220, the buffer layer 420, the light conversion part 300, the adhesive layer 410, and the first substrate 110 may be entirely cut, and the first substrate 110 may be partially cut.

Accordingly, the cutting region CTA may expose an upper surface of the first substrate 110.

The third sealing part 530 is disposed inside the cutting region CTA. Accordingly, the third sealing part 530 is in contact with the first substrate 110. That is, a lower surface of the third sealing part 530 is in contact with the first substrate 110.

Accordingly, it is possible to prevent moisture from flowing into the adhesive layer. That is, the adhesive layer includes a separation portion. The separation portion is formed by the cutting region. The separation portion is filled with a sealing material to form a sealing part. Accordingly, it is possible to prevent moisture from flowing into the optical path control member through the sealing part disposed in the separation portion.

Referring to FIGS. 9 to 13, at least one protrusion 800 is disposed in the cutting region CTA. The protrusion 800 is in contact with the first substrate 110. The protrusion 800 may extend from the first substrate 110 toward the second substrate 120.

The protrusion 800 may be a region remaining when the cutting region CTA is formed. Accordingly, the protrusion 800 may include at least one of the second substrate 120, the second electrode 220, the buffer layer 420, the partition wall part 310 of the light conversion part, the adhesive layer 410, the second electrode 210, and the first substrate 110. Specifically, the protrusion 800 may include the same material as at least one of the second substrate 120, the second electrode 220, the buffer layer 420, the partition wall part 310 of the light conversion part, the adhesive layer 410, the second electrode 210, and the first substrate 110.

For example, the protrusion 800 may include the same material as the first substrate 110. Alternatively, the protrusion 800 may include the same material as the first electrode 210. Alternatively, the protrusion 800 may include the same material as the adhesive layer 410. Alternatively, the protrusion 800 may include the same material as the partition wall part 310. Alternatively, the protrusion 800 may include the same material as the buffer layer 420. Alternatively, the protrusion 800 may include the same material as the second electrode 220. Alternatively, the protrusion 800 may include the same material as the second substrate 120.

For example, the protrusion 800 may include different layers according to a height (h) of the protrusion.

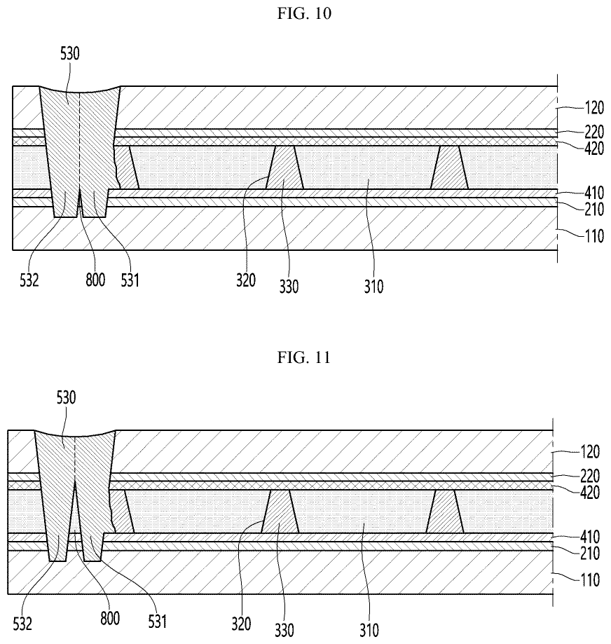

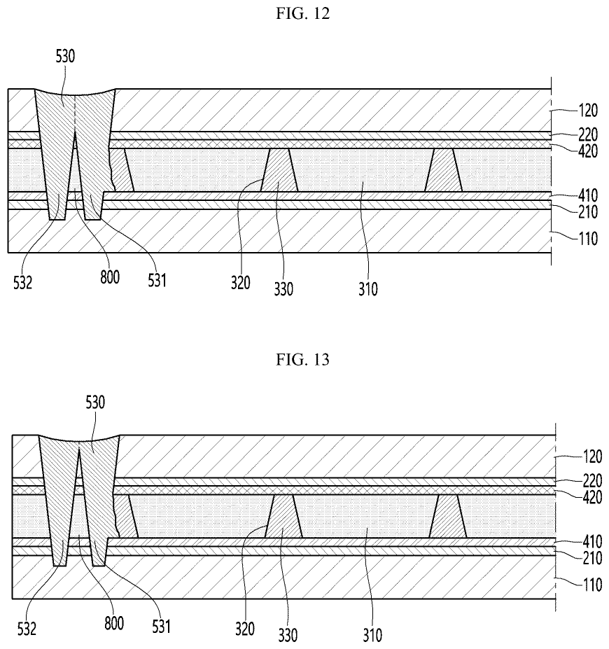

Referring to FIG. 9, the protrusion 800 may include the first substrate 110, the first electrode 210, the adhesive layer 410, and the partition wall part 310. Alternatively, referring to FIG. 10, the protrusion 800 may include the first substrate 110, the first electrode 210, and the adhesive layer 410. Alternatively, referring to FIG. 11, the protrusion 800 may include the first substrate 110, the first electrode 210, the adhesive layer 410, the partition wall part 310, and the buffer layer 420. Alternatively, referring to FIG. 12, the protrusion 800 may include the first substrate 110, the first electrode 210, the adhesive layer 410, the partition wall part 310, the buffer layer 420, and the second electrode 420. Alternatively, referring to FIG. 13, the protrusion 800 may include the first substrate 110, the first electrode 210, the adhesive layer 410, the partition wall part 310, the buffer layer 420, the second electrode 420, and the second substrate 120.

The layers of the protrusion 800 are related to a height h and a width w1 of the protrusion 800. For example, as the height h of the protrusion 800 increases, the layer of the protrusion 800 increases. Also, as the width w1 of the protrusion 800 increases, the layer of the protrusion 800 increases.

The width w1 of the protrusion may be formed in a set range. The width w1 of the protrusion may be defined as a maximum width of the protrusion. The width w1 of the protrusion may be defined as a maximum width in a direction parallel to the first direction 1D.

The width w1 of the protrusion may be 20 μm or more. More specifically, the width w1 of the protrusion may be 10 μm to 20 μm or more, or 50 μm or more. Alternatively, the width w1 of the protrusion may be 10 μm to 2000 μm, 20 μm to 300 μm, 30 μm to 200 μm, or 50 μm to 100 μm. When the width w1 of the protrusion is less than 10 μm, a residual region in the cutting region CTA may be very small. Accordingly, the protrusion may not be formed. Also, when the width w1 of the protrusion is greater than 2000 μm, the width of the cutting region is increased by the protrusion. Accordingly, a bezel region of the optical path control member may be increased.

The cutting region CTA may include a first cutting region CTA1 and a second cutting region CTA2. The first cutting region CTA1 is adjacent to the receiving part 320. In detail, the first cutting region CTA1 is closer to the receiving part 320 than the second cutting region CTA2. In more detail, the first cutting region CTA1 is closer to the receiving part 320 disposed in the effective region than the second cutting region CTA2.

The first cutting region CTA1 and the second cutting region CTA2 may be partially spaced apart from each other by the protrusion 800. That is, the first cutting region CTA1 and the second cutting region CTA2 are spaced apart from each other in a region in which the protrusion 800 is disposed. Also, the first cutting region CTA1 and the second cutting region CTA2 are in contact with each other on an upper portion of the protrusion 800 where the protrusion 800 is not disposed. Accordingly, the first cutting region CTA1 and the second cutting region CTA2 are integrally formed as a whole.

The first cutting region CTA1 and the second cutting region CTA2 may be formed by different processes. That is, the first cutting region CTA1 and the second cutting region CTA2 may be sequentially formed.

For example, the first cutting region CTA1 may be formed first. Subsequently, the second cutting region CTA2 may be formed. That is, the first cutting region CTA1 adjacent to the receiving part 320 may be formed first.

In this case, the second cutting region CTA2 may be formed at a position partially overlapping the first cutting region CTA1.

That is, the width and height of the protrusion 800 may change according to an overlapping size of the first cutting region CTA1 and the second cutting region CTA2.

A sealing material is filled in the cutting region CTA. Accordingly, the third sealing part 530 may be formed. The third sealing part 530 may be in contact with at least one of an inner surface of the cutting region CTA and a surface of the protrusion 800. In detail, the third sealing part 530 may be in contact with the inner surface of the cutting region CTA and the surface of the protrusion 800.

The third sealing part 530 may be partially disposed inside the receiving part 320 in addition to the cutting region CTA.

The third sealing part 530 may be divided into a plurality of third sealing parts 530 by the protrusion 800. In detail, the third sealing part 530 may include a third-first sealing part 531 and a third-second sealing part 532.

The third-first sealing part 531 is disposed in the first cutting region CTA1. Also, the third-second sealing part 532 is disposed in the second cutting region CTA.

The third-first sealing part 531 is adjacent to the receiving part 320. That is, the third-first sealing part 531 is closer to the receiving part 320 than the third-second sealing part 532. Accordingly, the third-first sealing part 531 is in contact with the light conversion material 330.

The third-first sealing part 531 and the third-second sealing part 532 may be partially separated from each other by the protrusion 800. That is, the third-first sealing part 531 and the third-second sealing part 532 are separated from each other in a region in which the protrusion 800 is disposed. Also, the protrusion 800 is in contact with each other on the upper part of the protrusion 800 in which the protrusion 800 is not disposed. Accordingly, the third-first sealing part 531 and the third-second sealing part 532 may be integrally formed as a whole.

The third sealing part 530 may be in contact with the inner surface of the cutting region CTA inside the cutting region CTA. Furthermore, the third sealing part 530 may be in contact with the surface of the protrusion 800 inside the cutting region CTA.

Accordingly, a contact area of the third sealing part 530 may be increased. That is, the third sealing part 530 is in contact with the inner surface of the cutting region CTA and the surface of the protrusion 800. Accordingly, the contact area of the third sealing part 530 may be increased.

Therefore, the adhesive force of the sealing part disposed in the cutting region is increased. Accordingly, the sealing characteristic through the third sealing part is improved. Also, the third sealing part may be prevented from being separated. Therefore, the reliability of the optical path control member may be improved.

The third sealing part 530 may have a predetermined width. In this case, the width w2 of the third sealing part 530 may be defined as a maximum width of the third sealing part.

Specifically, the width w2 of the third sealing part may be 100 μm or more, 300 μm or more, or 500 μm or more. Specifically, the width w2 of the third sealing part may be 100 μm to 1000 μm.

In addition, the width w2 of the third sealing part may be formed to have a width at a ratio set to the width of the effective region. The ineffective region may be defined as a region in which a path of light does not change in the optical path control member.

That is, the optical path control member may include an effective region and an ineffective region. The effective region may change a path of light due to a light conversion material. Also, the ineffective region may be a region in which a light conversion material is not disposed. The ineffective region is disposed in an outer region of the effective region. The ineffective region may be disposed surrounding the effective region.

A width w2 of the third sealing part may be 50% or more of a total width w3 of the ineffective region. In detail, the width w2 of the third sealing part may be 55% or more of the total width w3 of the ineffective region. In more detail, the width w2 of the third sealing part may be 60% or more of the total width w3 of the ineffective region UA. In more detail, the width w2 of the third sealing part may be 50% to 70% of the total width w3 of the ineffective region UA. In more detail, the width w2 of the third sealing part may be 55% to 65% of the total width w3 of the ineffective region.

Preferably, the width w3 of the ineffective region may be the width of the ineffective region in which the sealing part is disposed to be compared. For example, a left width w3 of the ineffective region may be compared with a left width w2 of the sealing part.

Also, one side of the width w3 of the ineffective region may be the same as one side of the width w2 of the sealing part. Also, the other side of the width w3 of the ineffective region may be an outermost side of the optical path control member.

When the width w2 of the third sealing part is less than 50% of the total width w3 of the ineffective region, external moisture may be introduced into the receiving part.

In addition, when the width w2 of the third sealing part exceeds 70% of the total width w3 of the ineffective region, the third sealing part is disposed over an entire area of the ineffective region. Accordingly, it becomes difficult to use the ineffective region for other purposes.

In the above description, it has been described that the cutting region CTA includes the protrusion 800, but the embodiment is not limited thereto.

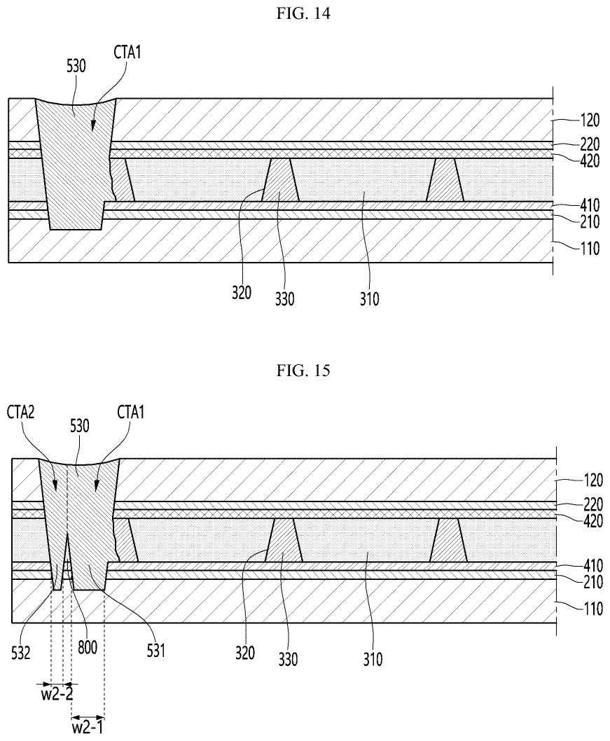

Referring to FIG. 14, the protrusion 800 is not disposed inside the cutting region CTA. That is, a thickness of the protrusion 800 disposed inside the cutting region CTA may be 0.

Therefore, the third sealing part 530 may be in contact with only the inner surface of the cutting region CTA and the upper surface of the first substrate 110 inside the cutting region CTA.

That is, when the second cutting region CTA2 is formed, a size at which the second cutting region CTA overlaps the first cutting region CTA1 may increase. Accordingly, a residual region is not formed between the first cutting region CTA1 and the second cutting region CTA2. Accordingly, the protrusion is not formed.

Accordingly, the width of the cutting region is reduced. Also, the width of the third sealing part disposed inside the cutting region is reduced. Accordingly, the area in which the third sealing part is disposed in the ineffective region of the optical path control member may be reduced.

Referring to FIG. 15, the third-first sealing part 531 and the third-second sealing part 532 may have different widths.

A width of the first cutting region CTA1 may be different from a width of the second cutting region CTA2. For example, the width of the first cutting region CTA1 may be greater than the width of the second cutting region CTA2. Specifically, a maximum width of the first cutting region CTA1 may be greater than a maximum width of the second cutting region CTA2. Also, a minimum width of the first cutting region CTA1 may be greater than a minimum width of the second cutting region CTA2.

The third-first sealing part 531 is disposed inside the first cutting region CTA1. Also, the third-second sealing part 532 is disposed inside the second cutting region CTA2. Accordingly, a width (w2-1) of the third-first sealing part 531 may be greater than a width (w2-2) of the third-second sealing part 532.

The third-first sealing part 531 is formed to have a larger width than the third-second sealing part 532, and thus, moisture introduced into the receiving part 320 may be effectively blocked. That is, the width of the third-first sealing part 531 which is in direct contact with the light conversion material inside the receiving part 320 may be formed to be large, and, accordingly, it is possible to more effectively block moisture that may penetrate into the receiving part 320 from the outside.

That is, the inflow of moisture may be prevented primarily by the third-second sealing part 532. Also, moisture passing through the third-second sealing part 532 is blocked by the third-first sealing part 531 having a large area. Alternatively, moisture flowing into another path is also blocked by the third-first sealing part 531. Accordingly, it is possible to effectively prevent moisture from flowing into the receiving part 320.

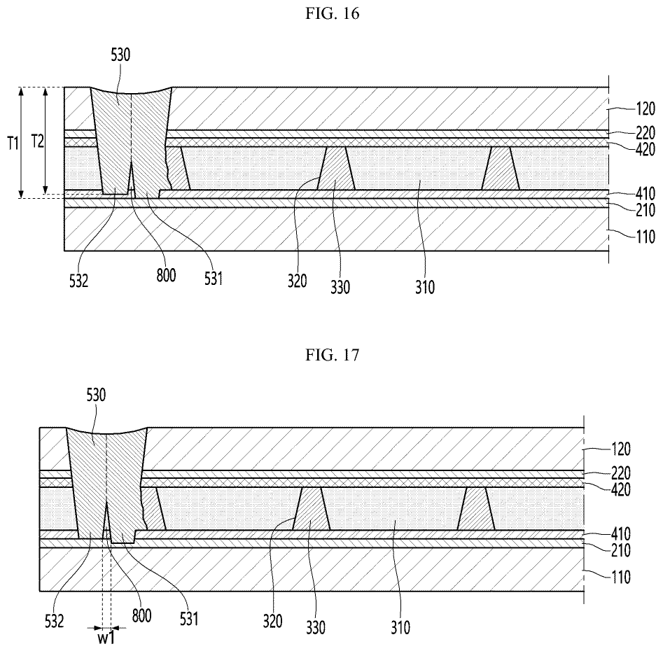

Referring to FIG. 16, the third sealing part 530 comes in contact with the first electrode 210 and the adhesive layer 410. Specifically, the cutting region may be formed by partially removing the adhesive layer 410. Alternatively, the cutting region may be formed by removing all of the adhesive layer 410. Accordingly, the third sealing part 530 is in contact with an upper surface and an inner surface of the adhesive layer 410. Also, the third sealing part 530 is in contact with the upper surface of the first electrode 210.

Specifically, at least one of the first cutting region CTA1 and the second cutting region CTA2 may be formed by partially removing the adhesive layer 410. For example, the first cutting region CTA1 may be formed by removing all of the adhesive layer 410. Also, the second cutting region CTA2 may be formed by partially removing the adhesive layer 420.

The second cutting region CTA2 may be formed by removing the adhesive layer 410 by a thickness of 50% or more. When formed by removing a thickness of less than 50% of the thickness of the adhesive layer 410, moisture may be introduced by a remaining adhesive layer.

Accordingly, the third-first sealing part 531 may be disposed in contact with an upper surface of the first electrode 210. Also, the third-second sealing part 532 may be disposed in contact with the upper surface and the inner surface of the adhesive layer 410.

An adhesive layer in at least one of a plurality of cutting regions remains to be formed. Therefore, the adhesive force may be improved by the remaining adhesive layer. Therefore, the adhesive force between the light conversion part 300 and the first electrode 210 may be improved.

Referring to FIG. 17, the third sealing part 530 is in contact with the first electrode 210. Specifically, the cutting region is formed by partially removing the first electrode 210. Accordingly, the third sealing part 530 is disposed in contact with the upper surface and the inner surface of the first electrode 420.

Specifically, at least one of the first cutting region CTA1 and the second cutting region CTA2 is formed by partially removing the first electrode 210. For example, the first cutting region CTA1 may be formed by partially removing the first electrode 210. Also, the second cutting region CTA2 may be formed by removing the adhesive layer 420.

The first cutting region CTA1 may be formed by removing the first electrode 210 by a thickness of 50% or less. When formed by removing the first electrode 210 by more than 50% of the thickness, the conductivity of the first electrode 210 may be reduced. Also, the first electrode inside the first cutting region CTA1 may be short-circuited. Accordingly, the electrical characteristics of the optical path control member may be reduced.

Accordingly, the third-first sealing part 531 may be disposed to be in contact with the upper surface and the inner surface of the first electrode 210. Also, the third-second sealing part 532 may be disposed to be in contact with the upper surface of the first electrode 210.

A first electrode in at least one cutting region among a plurality of cutting regions is partially removed to be formed. Accordingly, since the depth of the cutting region is increased, an area in which the sealing part is disposed is increased. Accordingly, adhesion characteristics and sealing characteristics of the sealing part may be improved.

Referring to FIGS. 16 and 17, the third-first sealing part 531 and the third-second sealing part 532 may have different thicknesses.

In detail, a thickness T1 of the third-first sealing part 531 may be greater than a thickness T2 of the third-second sealing part 532. For example, the thickness T1 of the third-first sealing part 531 may be greater than one time and equal to or less than 1.5 times the thickness T2 of the third-second sealing part 532. In more detail, the thickness T1 of the third-first sealing part 531 may be greater than one time and equal to or less than 1.3 times the thickness T2 of the third-second sealing part 532. In more detail, the thickness T1 of the third-first sealing part 531 may be greater than one time and equal to or less than 1.1 times the thickness T2 of the third-second sealing part 532.

When the thickness T1 of the third-first sealing part 531 is greater than 1.5 times the thickness T2 of the third-second sealing part 532, an area in which the third-second sealing part 532 is disposed is reduced. Accordingly, sealing characteristics of the optical path control member may be reduced.

The third-first sealing part 531 and the third-second sealing part 532 are formed to have different thicknesses. Accordingly, the width w1 of the protrusion 800 is defined as a distance from a lower surface of the sealing part having a small thickness to a side surface of the sealing part having a large thickness.

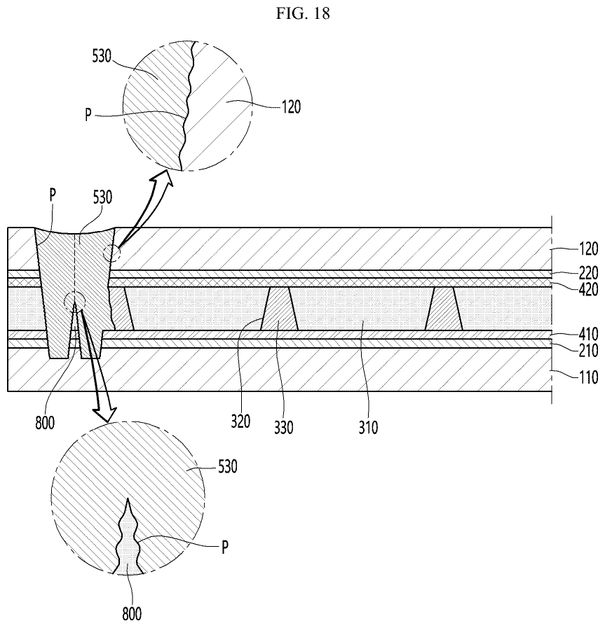

Referring to FIG. 18, the cutting region CTA may include a plurality of pattern portions. Specifically, the plurality of pattern portions may include a plurality of patterns P having an uneven shape.

The cutting region CTA may be formed using a laser. Accordingly, the inner surface of the cutting region CTA contacts the laser. Accordingly, a plurality of patterns may be formed on the inner surface of the cutting region CTA.

The pattern P can increase a surface roughness of the inner surface and the protrusion of the cutting region CTA. Accordingly, the surface roughness of the inner surface and the protrusion 800 of the cutting region CTA can be greater than the surface roughness of the first substrate 110 and the second substrate 120.

Adhesive force of the third sealing part may be improved by the patterns P. That is, a contact area of the third sealing part 530 is increased by the patterns P. Therefore, the adhesive force of the third sealing part 530 may be improved.

Accordingly, it is possible to prevent the third sealing part from being peeled off. Thereby, reliability of the optical path control member may be secured.

A sealing part of an optical path control member according to an embodiment has improved adhesive force.

The sealing part is disposed inside the cutting region, and a protrusion is formed inside the cutting region. Accordingly, a contact area of the sealing part may be increased. Accordingly, it is possible to prevent the sealing part from being peeled off.

In addition, the optical path control member according to the embodiment has a reduced bezel region.

In detail, a protrusion is formed inside the cutting region. The cutting region is partially separated by the protrusion. Accordingly, the cutting region may include a plurality of cutting regions.

The plurality of cutting regions are formed to have different sizes. For example, the plurality of cutting regions may have different widths and depths.

A size of a cutting region adjacent to a receiving part among a plurality of cutting regions may be formed to be large. In addition, a size of a cutting region far from the receiving part may be formed small. Accordingly, the bezel region may be reduced while maintaining the sealing characteristics.

Accordingly, the optical path control member according to an embodiment may have improved reliability. Also, the optical path control member according to an embodiment may have a narrow bezel.

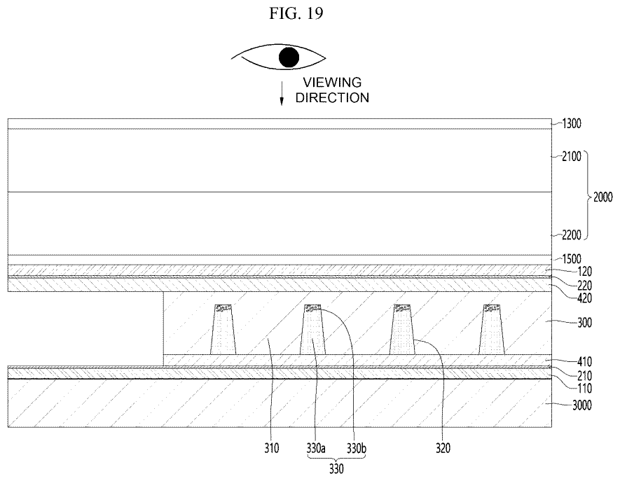

Hereinafter, a display device and a display device to which an optical path control member according to an embodiment is applied will be described with reference to FIGS. 19 to 23.

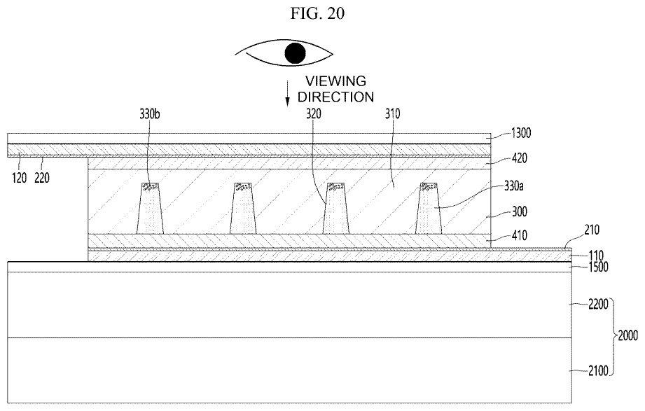

Referring to FIGS. 19 and 20, the optical path control member 1000 according to the embodiment may be disposed on or below the display panel 2000.

The display panel 2000 and the optical path control member 1000 may be disposed to be adhered to each other. For example, the display panel 2000 and the optical path control member 1000 may be adhered to each other by an adhesive layer 1500. The adhesive layer 1500 may be transparent. For example, the adhesive layer 1500 may include an optical transparent adhesive material.

The display panel 2000 may include a first base substrate 2100 and a second base substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 19, the optical path control member may be disposed under the liquid crystal panel and on the backlight unit 3000, and the optical path control member may be disposed between the backlight unit 3000 and the display panel 2000.

Alternatively, as shown in FIG. 20, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second base substrate and a first base substrate of the display panel, or the like.

In addition, it is shown in the drawings that the light conversion part of the optical path control member according to the embodiment is in a direction parallel or perpendicular to an outer surface of the second substrate, but the light conversion part is formed to be inclined at a predetermined angle from the outer surface of the second substrate. Through this, a moiré phenomenon occurring between the display panel and the optical path control member may be reduced.

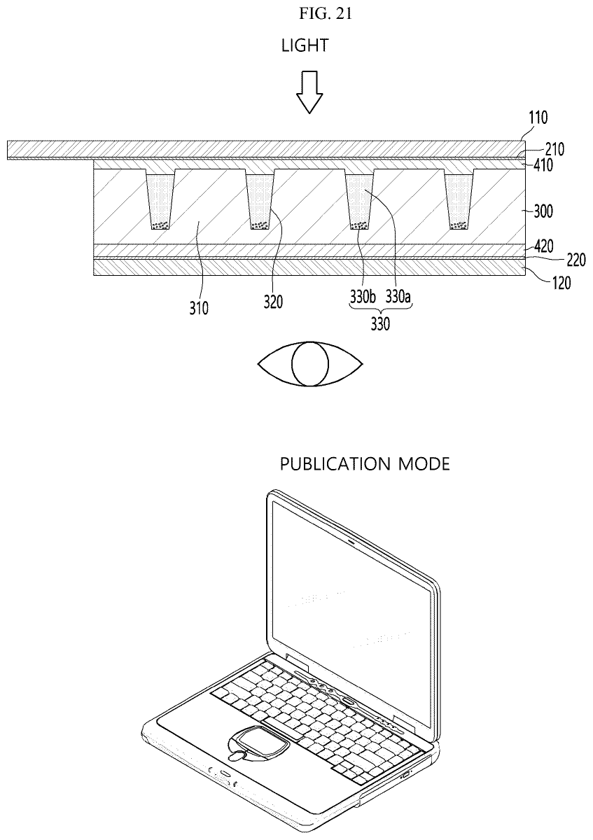

Referring to FIGS. 21 to 23, the optical path control member according to the embodiment may be applied to a display device that displays a display.

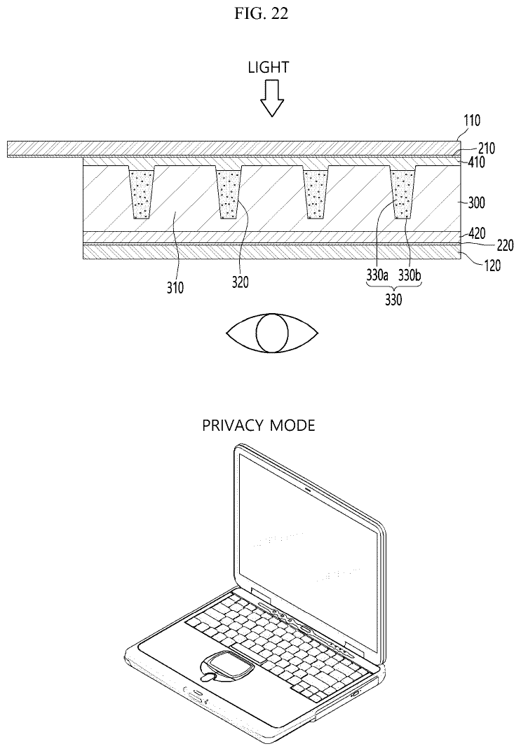

For example, when power is applied to the optical path control member as shown in FIG. 21, the receiving part functions as the light transmitting part, so that the display device may be driven in the publication mode, and when power is not applied to the optical path control member as shown in FIG. 22, the receiving part functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

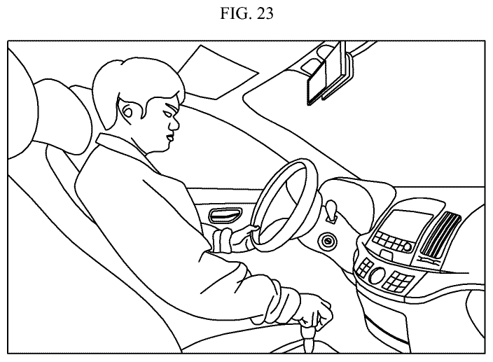

In addition, referring to FIG. 23, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate;
an adhesive layer disposed on the first electrode;
a light conversion part disposed on the adhesive layer;
a second electrode disposed on the light conversion part;
a second substrate disposed on the second electrode; and,
a sealing part disposed in a cutting region formed by removing the second substrate, the second electrode, the light conversion part, and the adhesive layer,
wherein at least one protrusion is provided in the cutting region while extending in a direction from the first electrode toward the second substrate, and
wherein a thickness of the protrusion is smaller than a depth of the cutting region or a thickness of the sealing part.

2. The optical path control member of claim 1, comprising:
a buffer layer disposed between the second electrode and the light conversion part, and
wherein the protrusion includes a same material as at least one of the first electrode, the adhesive layer, the light conversion part, the buffer layer, the second electrode, or the second substrate.

3. The optical path control member of claim 1, wherein a maximum width of the protrusion is 20 μm to 200 μm.

4. The optical path control member of claim 1, wherein a maximum width of the sealing part is 100 μm to 1000 μm.

5. The optical path control member of claim 1, wherein the optical path control member includes an effective region in which a path of light is changed and an ineffective region provided outside the effective region, and
wherein a maximum width of the sealing part is 50% to 70% of a total width of the ineffective region.

6. The optical path control member of claim 1, wherein the cutting region includes a first cutting region and a second cutting region connected to the first cutting region, wherein the first cutting region and the second cutting region are partially spaced apart from each other by the protrusion.

7. The optical path control member of claim 6, wherein the light conversion part includes a receiving part and a partition wall part alternately arranged,
wherein a light conversion material is disposed in the receiving part, and
wherein the first cutting region is disposed closer to the receiving part than is the second cutting region.

8. The optical path control member of claim 7, wherein a width of the sealing part in the first cutting region and a width of the sealing part in the second cutting region are different.

9. The optical path control member of claim 8, wherein the width of the sealing part in the first cutting region is greater than the width of the sealing part in the second cutting region.

10. The optical path control member of claim 9, wherein at least one of the sealing part in the first cutting region or the sealing part in the second cutting region is in contact with a lower surface and an inner surface of the adhesive layer.

11. The optical path control member of claim 6, wherein at least one of the first cutting region or the second cutting region is formed by partially removing the first electrode, and
wherein at least one of a sealing part in the first cutting region or a sealing part in the second cutting region is in contact with a lower surface and an inner surface of the first electrode.

12. The optical path control member of claim 9, wherein a thickness of a sealing part in the first cutting region and a thickness of a sealing part in the second cutting region are different.

13. The optical path control member of claim 12, wherein the thickness of the sealing part in the first cutting region is greater than that of the sealing part in the second cutting region.

14. The optical path control member of claim 1, wherein a surface roughness of each of an inner surface of the cutting region and a surface of the protrusion are greater than a surface roughness of a surface of each of the first substrate and the second substrate.

15. The optical path control member of claim 1, wherein a lower surface of the sealing part includes first and second lower surfaces spaced apart from each other with the protrusion interposed therebetween.

16. The optical path control member of claim 15, wherein an upper surface of the sealing part is spaced apart from the protrusion.

17. The optical path control member of claim 15, wherein an upper surface of the sealing part includes a first upper surface overlapping the first lower surface in a thickness direction, a second upper surface overlapping the second lower surface in the thickness direction, and a third upper surface between the first upper surface and the second upper surface.

18. The optical path control member of claim 1, comprising a plurality of protrusions, wherein the sealing part branches between the protrusions, and
wherein a point at which the branch starts in the sealing part is lower than an upper surface of the sealing part.

19. The optical path control member of claim 1, wherein the sealing part includes first and second sealing parts extending in a first horizontal direction and spaced apart from each other in a second horizontal direction different from the first horizontal direction, and
wherein the protrusion includes a first protrusion connected to the first sealing part and extended in the first horizontal direction, and a second protrusion connected to the second sealing part and extended in the first horizontal direction.

20. The optical path control member of claim 19, wherein the sealing part includes third and fourth sealing parts that extend in the second horizontal direction and are spaced apart from each other in the first horizontal direction, and
wherein the protrusion includes a third protrusion connected to the third sealing part and extended in the second horizontal direction, and a fourth protrusion connected to the fourth sealing part and extended in the second horizontal direction.
